(19) United States
(12) Patent Application Publication
(10) Pub. No.: US 2024/0373544 A1
(43) Pub. Date: Nov. 7, 2024

(54) CIRCUIT ASSEMBLY INCLUDING GALLIUM NITRIDE DEVICES

(71) Applicant: Murata Manufacturing Co., Ltd., Nagaokakyo-shi, Kyoto-fu (JP)

(72) Inventors: Jahangir AFSHARIAN, Markham (CA); Bing GONG, Markham (CA); Ning ZHU, Markham (CA); Anil YARAMASU, Markham (CA)

(21) Appl. No.: 18/285,541

(22) PCT Filed: Apr. 8, 2022
(86) PCT No.: PCT/US2022/024033

§ 371 Date: Oct. 4, 2023

Related U.S. Application Data
(60) Provisional application No. 63/173,004, filed on Apr. 9, 2021.

(51) Int. Cl. H05K 1/02; H05K 3/00; H05K 7/20

(52) U.S. Cl. CPC H05K 1/021; H05K 3/0061; H05K 7/205; H05K 2201/066

(57) ABSTRACT

A circuit assembly includes a printed circuit board (PCB) with a metal inlay and an integrated metal substrate on a first side of the metal inlay, a switching device connected to a second side of the metal inlay opposite to the first side, and a thermal path between the switching device and the metal substrate via the metal inlay.

### CROSS REFERENCE TO RELATED APPLICATIONS

This application claims the benefit of U.S. Patent Application No. 63/173,004 filed on Apr. 9, 2021. The entire contents of this application are hereby incorporated by reference.

### BACKGROUND OF THE INVENTION

### 1. Field of the Invention

The present invention relates to a circuit assembly including, for example, gallium nitride (GaN) devices for high-power-density power-supply applications.

### 2. Description of the Related Art

FIG. 1 is a circuit diagram of an AC-DC rectifier using a totem-pole power factor correction (PFC) topology. The main benefit of this totem-pole PFC topology compared to a classic boost PFC is that it is a bridgeless circuit, meaning that it does not include a rectifier diode bridge at its input. Therefore, the associated rectifier bridge losses are eliminated, leading to higher efficiency and power density. A benefit of using complementary enhancement-mode (e-mode) gallium nitride (GaN) semiconductors—with GaN being a wide-bandgap (WBG) material—is the complete elimination of any reverse recovery charge. Therefore, GaN devices work well with half-bridge, hard-switching circuitry in applications that cannot be addressed by conventional high-voltage superjunction power semiconductors. Under these conditions, the totem-pole PFC topology as shown in FIG. 1 is well suited to work with GaN devices.

FIG. 1 shows that GaN devices (within the dotted line box) are used as switches S₁ and S₂. A node between the switches S₁ and S₂ is connected to a terminal of an alternating current (AC) voltage source V_{AC} through an inductor, and a node between the switches S_{D1} and S_{D2} is connected to another terminal of the AC voltage source VAC. Each of a capacitor C and a resistor R is connected in parallel across the switches S_{D1} and S_{D2}. Switches S₁ and S₂ are switched at a high switching frequency and provide the function of a boost switch and a rectifier switch, while switches S_{D1} and S_{D2} are switched at the line frequency and provide the function of a line rectifier. The totem pole circuitry can reach higher density limits at higher efficiency compared to a classic boost PFC circuit.

FIG. 2 shows another example of a higher-power, hard-switched topology as a circuit diagram of a conventional three-phase, six-switch boost converter using GaN devices. GaN devices S₁-S₆ can be used to increase efficiency and power density over comparable circuitry without GaN devices. Each of the series-connected switches S₁ and S₂, switches S₃ and S₄, and switches S₅ and S₆ are connected in parallel to a direct current (DC) voltage source V_{DC}, and a node between each of the series-connected switches S₁ and S₂, switches S₃ and S₄, and switches S₅ and S₆ is connected to an inductor L_{f}.

Increasing the power density of power supplies operating at higher switching frequencies is desirable. FIG. 3 shows a half-bridge LLC converter circuit with GaN devices S₁ and S₂ (within the dotted line box) in a soft-switching topology that operates at much higher switching frequencies than Si-MOSFET devices. The half-bridge LLC converter includes a transformer that provides an isolation barrier that divides the circuit in a primary-side circuit connected to the primary winding of the transformer (on the left side of FIG. 3) and a secondary-side circuit connected to the secondary winding of the transformer (on the left side of FIG. 3). The primary-side circuit includes a switching circuit including series-connected GaN devices S₁ and S₂ that are connected in parallel with the DC voltage source V_{DC} and a resonant circuit that is connected between the switching circuit and the primary windings and that includes a resonant capacitor Cᵣ, resonant inductor Lᵣ, and magnetizing inductor Lₘ. The secondary-side circuit includes a rectifier circuit including switches Q₃ and Q₄. Using Si-MOSFET devices operating at a switching frequency above 350 kHz will increase the conduction losses due to the deadtime requirement of Si-MOSFET devices. A GaN device has a much smaller turn-off loss and required deadtime compared to Si-MOSFET devices so that it is more suitable to operate at higher frequencies. GaN devices can also be used in a full-bridge LLC converter configuration (not shown).

Due to its fast switching, a surface mounted package with low parasitic inductance is normally employed for GaN devices to reduce voltage spikes and ensure reliable operation. FIG. 4 shows a conventional GaN assembly with a GaN device shown as the top box and including a case 200 and device junction 201. The conventional structure with GaN devices on a laminated printed circuit board (PCB) 202 attached to a heatsink 203 can be used but suffers from the following drawbacks.

First, a large heatsink 203 is required. As shown in FIG. 4, the total thermal resistance from the device junction Tⱼ to ambient temperature T_{amb} can be calculated as: Tⱼ=Rth_jc+Rth_PCB+Rth_TIM+Rth_hsa, where Rth_jc is the thermal resistance of the device junction 201 to the case 200, Rth_PCB is the thermal resistance of the PCB 202, Rth_TIM is the thermal resistance of the thermal interface material (TIM) 204, and Rth_hsa is the thermal resistance of the heatsink 203 to the ambient temperature T_{amb}.

The thermal resistance of the PCB Rth_PCB is the dominant thermal resistor because of the low thermal conductivity of FR4, which is the most used PCB material. The heat generated by the GaN devices will create hot spots on the PCB 202 due to the concentrated surface area of the GaN devices. The high temperature of the GaN devices will in turn increase their drain-source on resistance (Rds_on). Therefore, the maximum power that can be delivered by the overall assembly is normally limited by the GaN device's maximum junction temperature, even when the current is well below the GaN device's rated current. To maximize the output power of the GaN devices, the heatsink temperature needs to be reduced to well below the case temperature of the GaN devices due to the large thermal resistance of the PCB 202. The effectiveness of the heatsink 203 can be significantly reduced when the heatsink temperature is low. In that case, the temperature difference between the heatsink 203 and ambient surrounding is small. Therefore, a large heatsink 203 is required, but the large heatsink 203 increases the power density and the overall cost of the circuit assembly.

Additionally, there are high losses at high current in conventional assemblies. Because a conventional PCB has limited copper for conducting current, the conduction loss at high current is large and increases the thermal stress of the assembly.

To address these problems in conventional assemblies that include GaN devices, a large heatsink has been used to increase cooling and/or a complicated bus bar has been used on the PCB to provide higher current. Additionally, the output power of conventional assemblies has been reduced to meet the temperature and rated-current specifications of the GaN devices. Additionally, thermal vias have been incorporated into the PCB to reduce the thermal resistance of the PCB.

Optionally, to address the problems of a conventional GaN assembly, an insulated metal substrate (IMS) 301 has been used to transfer heat as shown in FIGS. 5 and 6. FIGS. 5 and 6 are views of a horizontal IMS evaluation gate driver board, part number GSP665x-EVBIMS2 made by GaN Systems Co. An IMS 301 in FIG. 6, also called a metal core PCB, is made of a metal plate, thermal insulating layers, and a copper foil, which has special magnetic conductivity, excellent heat dissipation, high mechanical strength, and good processing performance. The IMS technology is very efficient for higher power applications featuring high power losses at limited layout density such as power-LED modules. However, using an IMS 301 limits layout density because it has only one or two layers for trace routing. Therefore, except the GaN devices, all the other circuitry including the gate driver circuit, isolated power supply, and input connectors are located on a standard PCB 302. The PCB 302 is attached to the IMS 301 through connectors. However, there is a large gap between the IMS 301 and PCB 302 because of the connectors. As shown in FIG. 6, this large gap will create a large power loop inductance path 303 that includes the DC decoupling capacitors 304, the IMS 301, and the PCB 302. The large power loop inductance path 303 can cause large drain-source voltage spikes and ringing of the GaN devices during transients because of fast switching of the GaN devices. Especially when the switching current is large, this ringing of the GaN devices can cause a high voltage difference over time (dv/dt) at the middle point of the half bridge, which can result in false turn-on of the switches. In addition, a high-spike voltage increases the voltage stress on the GaN devices and can result in the GaN devices exceeding their voltage rating. Therefore, these drawbacks make this conventional configuration not practical in power supply applications.

### SUMMARY OF THE INVENTION

To overcome the problems described above, preferred embodiments of the present invention provide circuit assemblies each including high-power switching devices, such as GaN devices, on an inlay PCB and including an integrated metal substrate, which can significantly reduce the thermal resistance between the high-power switching devices and the ambient surroundings.

Additionally, preferred embodiments of the present invention provide circuit assemblies each with double-sided cooling to improve the thermal performance of the circuitry of the circuit assembly. Additionally, copper-filled vias in the PCB underneath the high-power switching devices significantly reduce the thermal resistance of the PCB.

An inlay PCB with high current and heat dissipation according to a preferred embodiment of the present invention can include:
1. A metal inlay, e.g., a copper inlay, that functions as a bus bar and a heatsink to significantly reduce conduction loss at high current.
2. A metal inlay with a large surface area compared to a PCB without a metal inlay that provides greater heat dissipation, especially when it is attached to another heatsink, due to the significantly reduced thermal resistance of the inlay PCB.
3. Combinability with an IMS that achieves very high power density and a much simplified manufacturing process of the GaN assembly by eliminating a separate heatsink.

A gate-driver PCB with an isolated power supply that is separate from the switching-device PCB according to a preferred embodiment of the present invention can provide several benefits, including:
1. Better thermal cooling and higher current capability of the switching-device PCB because the high current routing on the switching-device PCB can be improved or optimized by separating the gate driver circuitry from the power routing, which can have a high current.
2. An ability to use a transformer with a planar structure that is cost effective because the transformer with a planar structure can be integrated with the gate-driver PCB and more easily assembled.
3. An ability to use a winding arrangement of the transformer that can balance low inter-winding capacitance (low capacitance is important for reducing or minimizing common mode (CM) current injection due to fast-switching transients) with good coupling (low leakage inductance helps with open-loop output voltage regulation) and more than 1500-V isolation.
4. An ability to use a negative driver voltage that can be regulated to ensure that the gate threshold voltages of the devices are not exceeded during transients and to reduce or minimize reverse conduction losses.

According to a preferred embodiment of the present invention, a circuit assembly includes a printed circuit board (PCB) with a metal inlay and an integrated metal substrate on a first side of the metal inlay, a switching device connected to a second side of the metal inlay opposite to the first side, and a thermal path between the switching device and the metal substrate via the metal inlay.

The PCB can include copper-filled vias located beneath the switching device. The copper-filled vias can provide a portion of the thermal path between the switching device and the metal substrate. The metal inlay can be electrically connected to the switching device. The metal substrate can be an insulated metal substrate (IMS). The IMS can include copper.

The metal inlay can include copper. The metal inlay can include multiple portions, and each of the multiple portions can be connected to a different circuit node on the PCB. The switching device can be a gallium nitride switching device.

The above and other features, elements, steps, configurations, characteristics, and advantages of the present invention will become more apparent from the following detailed description of preferred embodiments of the present invention with reference to the attached drawings.

### BRIEF DESCRIPTION OF THE DRAWINGS

FIG. 1 is a circuit diagram of a conventional totem-pole bridgeless PFC circuit using GaN devices.

FIG. 2 is a circuit diagram of a conventional three-phase, six-switch boost converter circuit using GaN devices.

FIG. 3 is a circuit diagram of a conventional half-bridge LLC converter circuit using GaN devices.

FIG. 4 shows a conventional GaN circuit assembly according to the related art.

FIGS. 5 and 6 show a conventional GaN circuit assembly using an Insulated Metal Substrate.

FIGS. 7A and 7B a circuit assembly including a PCB with a cutout and an IMS.

FIG. 8 shows solder pads on an IMS that provide electrical connection to a gate-driver circuit.

FIG. 9 shows a PCB layout design of a circuit assembly.

FIG. 10 shows an inlay PCB according to a preferred embodiment of the present invention.

FIGS. 11A and 11B are cross-sections of an inlay PCB according to preferred embodiments of the present invention.

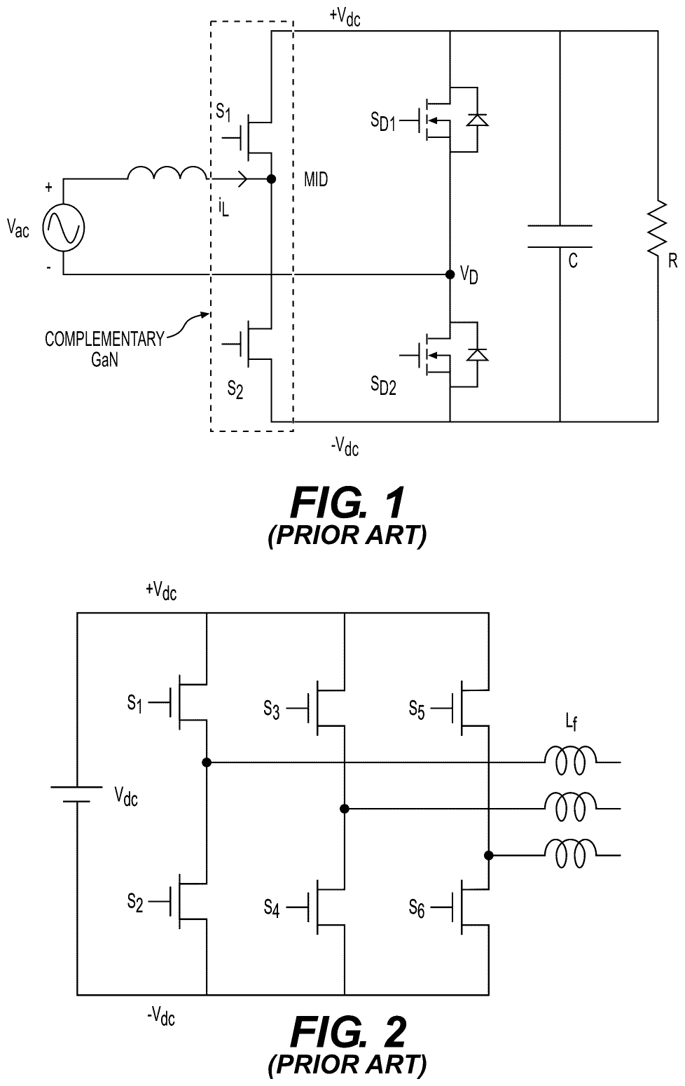

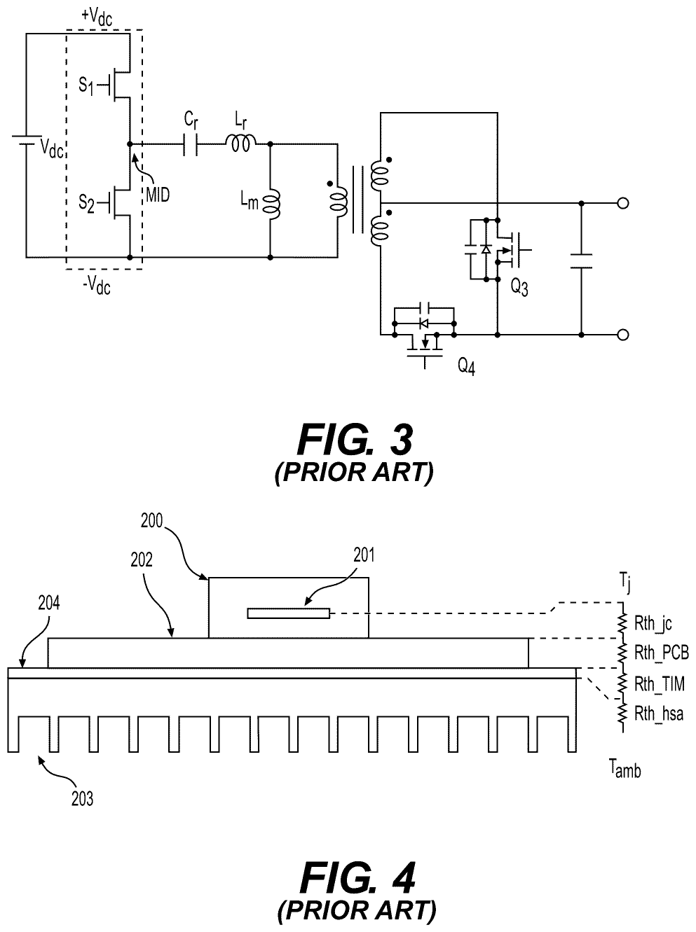

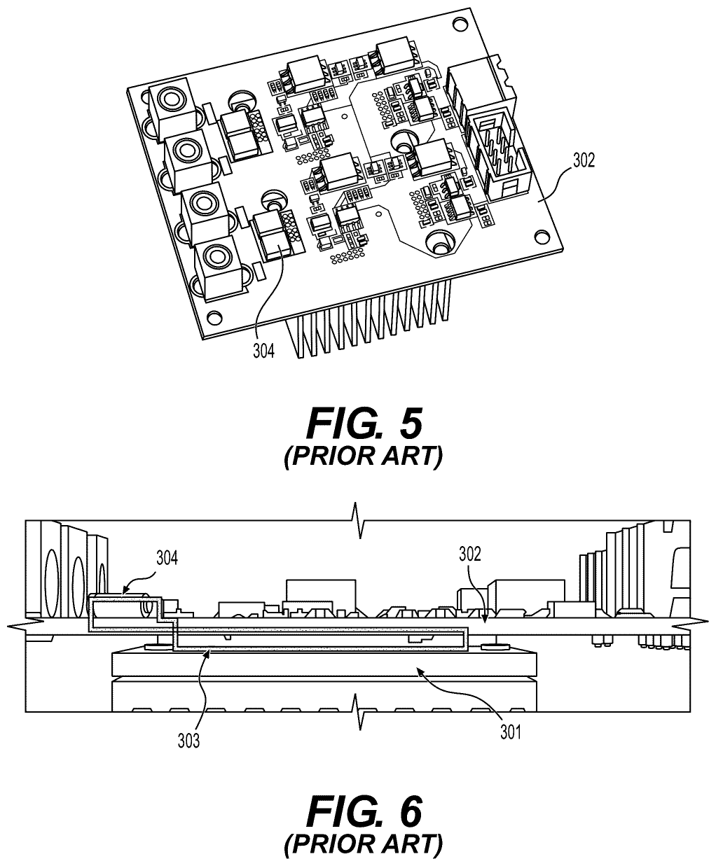

### DETAILED DESCRIPTION OF PREFERRED EMBODIMENTS

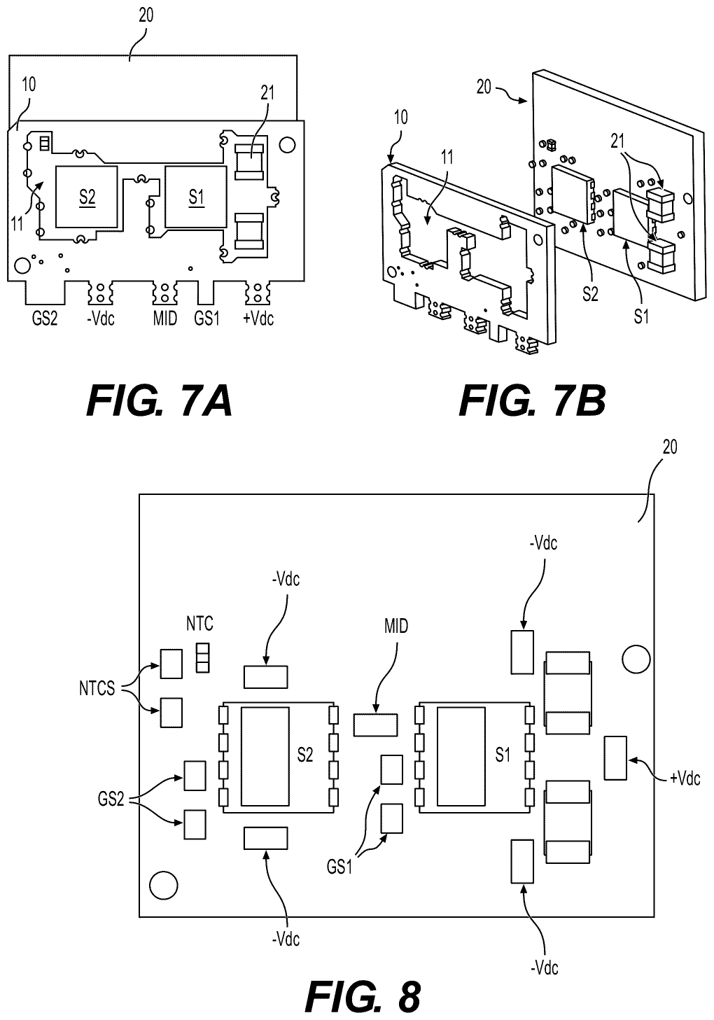

FIGS. 7A, 7B, and 8 show a circuit assembly with a PCB 10 with a cutout 11 and an IMS 20. FIG. 7A is a plan view of the circuit assembly, and FIG. 7B is an exploded view showing the IMS 20 and PCB 10 separated from each other. As shown in FIGS. 7A and 7B, the circuit assembly can include an IMS 20 with a PCB 10 attached to the IMS 20 with no gap or substantially no gap between the IMS 20 and the PCB 10 within manufacturing tolerances of the IMS 20 and the PCB 10. The opposing surfaces of IMS 20 and the PCB 10 can directly contact each other or substantially directly contact each within manufacturing tolerances of the IMS 20 and the PCB 10 so that there is no gap or substantially no gap within manufacturing tolerances of the IMS 20 and the PCB 10. FIG. 7A also shows locations to connect to the gates of switches S1 and S2 to provide gate driver signals GS1 and GS2 and to connect to the power connections +Vdc, −Vdc, MID, where MID can be the connection between the top and bottom switches in each leg of a converter. These voltages and signals can be connected to the IMS 20 through the PCB 10. FIG. 7B shows that the IMS 20 can include switches S1 and S2 that can be high-power switches such as GaN switches, and can include DC bus filter capacitors 21. FIG. 7B also shows that the PCB 10 includes a center portion that is cut out to define an opening or cutout 11 to fit around the switches S1 and S2, which can be, for example, GaN devices, and related circuitry on the IMS 21. The cutout 11 in the PCB 10 allows opposing surfaces of the PCB 10 and the IMS 20 to mate flush, or substantially flush within manufacturing tolerances of the PCB 10 and IMS 20, where there are no circuit components. Although one cutout 11 is shown in FIGS. 7A and 7B, it is possible to use more than one cutout.

For a high power density design, the IMS 20 can include copper because copper can provide better thermal performance with a smaller heatsink. It is also possible to use other materials for the IMS 20. The most used materials for the metal plate of the IMS 20 are aluminum and copper. An IMS 20 that is includes aluminum can be more cost effective. However, the material characteristics of copper offer many advantages in terms of thermal and electrical behavior compared to aluminum. Furthermore, the thermal expansion coefficient of copper compared to aluminum is advantageous, especially in supporting highly reliable solder connections between the PCB 10 and power devices.

Because of the limited layout density of an IMS 20, a PCB 20 can be used to provide more copper layers to route signals including the gate driver signals GS1 and GS2 and power connections +Vdc, −Vdc, MID to the main board to which the circuit assembly is attached (not shown). The connections to the main board can be provided by fingers or connectors on the PCB 10 that also provide mechanical support of the circuit assembly.

The layout design should reduce or minimize inductance of the high frequency AC current loop caused by the fast switching of the switching devices. Therefore, the cutout 11 in the PCB 10 is arranged so that the PCB 10 can be directly attached to the IMS 20 to eliminate the gap between the PCB 10 and the IMS 20. The electrical connections between the PCB 10 and IMS 20 can be provided by solder pads so that the PCB 10 can effectively become a surface mounted device. However, any other suitable method can be used to provide electrical connection between the PCB 10 and the IMS 20. FIG. 8 shows an example of the solder pads on the IMS 20. The solder pads used with the gates of switches S1 and S2, the power connections +Vdc, −Vdc, and MID provide solder connections to corresponding solder pads on the rear of the PCB 10. The negative-temperature-coefficient temperature sensing circuitry NTC can also be included to monitor temperature and to provide over-temperature protection via signals NTCS. Portions of the power supply gate drive circuit can also be integrated with the PCB 10 if there is enough board space. Alternatively, the power supply gate drive circuit can be located on a second gate driver PCB (not shown) (with the PCB 10 shown in FIGS. 7A, 7B, and 8 as the first PCB).

A heatsink can be directly attached to the metal plate of the IMS 20 without electrical insulation between the metal plate because the metal plate has been electrically isolated from the gate driver circuit by thermal insulating layers. A thermal interface material (TIM) such as a grease or a phase-change thermal material with very high thermal conductivity can be used to reduce or minimize any air voids between the metal plate and the heatsink.

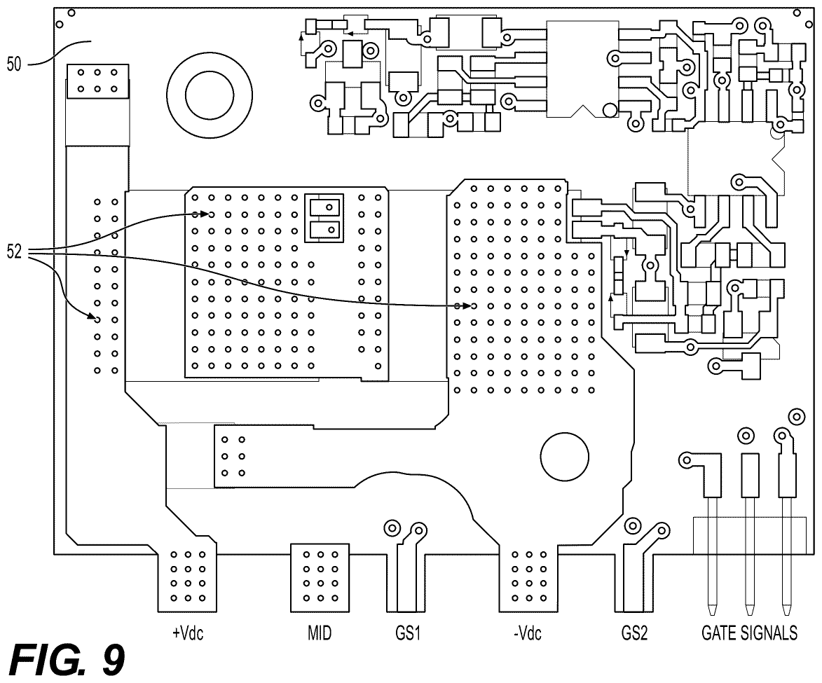

The cooling of the switching-device PCB 10 improves the overall thermal performance of the circuit assembly. Therefore, the thermal resistance of the switching-device PCB 10 needs to be reduced as small as possible to have the greatest effect on cooling. Similar to the copper-filled vias 52 shown in FIG. 9, copper-filled vias can be used in the PCB layout design that can significantly reduce the thermal resistance of the switching-device PCB 10. Reducing or minimizing the thickness of the PCB 10 can also help reduce the thermal resistance. A thickness of about 1 mm has been found to provide an acceptable balance between the thermal resistance and rigidness of the PCB 10. In this preferred embodiment of the present invention, the gate drive circuit of the circuit assembly is also integrated in the PCB 10 to reduce or minimize any looping of the gate driver signals GS1 and GS2.

Double-sided cooling can be applied to an IMS-based circuit assembly described with respect to FIGS. 7A, 7B, and 8. For example, a heatsink can be attached to the IMS 20, and a copper plate can contact the tops of the switches S1 and S2 through the cutout 11 in the PCB 10.

FIG. 9 shows an inlay PCB 50 that can be used to replace the switching-device PCB 10 as the first PCB to significantly reduce the conduction loss and increase the current handling capability of the circuit assembly. The inlay PCB 50 can include a copper inlay that can be integrated with a PCB.

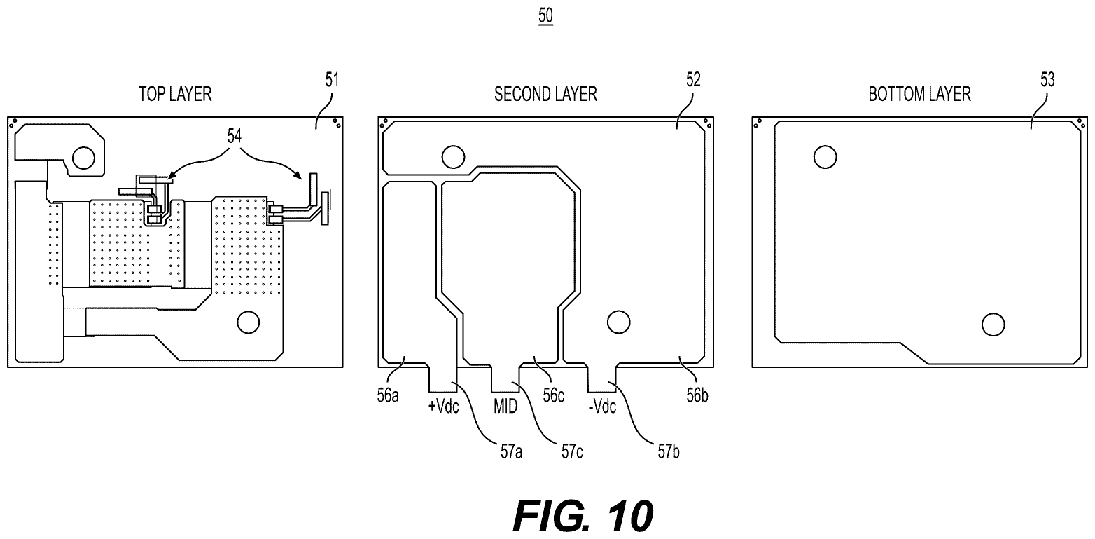

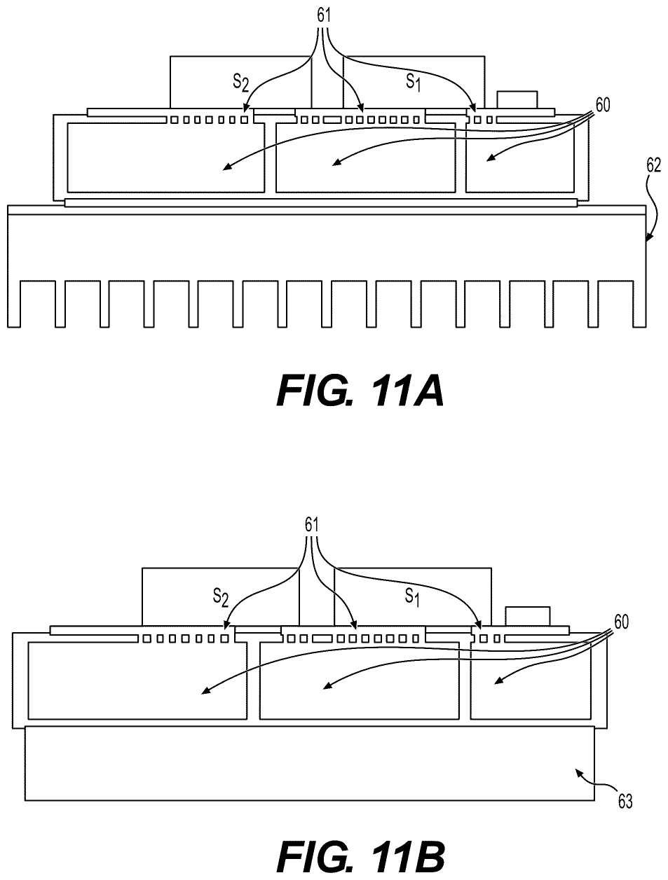

The inlay PCB 50 shown in FIG. 10 has top, second, and bottom layers 51, 52, 53 with a copper inlay with a thickness of, for example, about 1 mm-2 mm within manufacturing tolerances included in the second or middle layer. The copper inlay can have standard thicknesses of about 1.0 mm, about 1.5 mm, or about 2.0 mm, within manufacturing tolerances, or can have another suitable thickness. The copper inlay can be heavy ounce copper, including, e.g., 6-ounce or 10-ounce copper. As shown in FIG. 10, the top layer 51 can include pads or connectors 54 to connect to a gate-driver PCB (not shown in FIG. 10). In the second layer 52, the copper inlay is divided into three copper planes 56a, 56b, 56c connecting to the power connections +Vdc, −Vdc, and MID, respectively. Tabs 57a, 57b, 57c for each of these three copper planes 56a, 56b, 56c can extend outside the perimeter of the rectangular shape of the inlay PCB 50 to provide power connections to the main board (not shown). The copper planes 56a, 56b, 56c can be connected to the switching devices in the top layer through microvias, similar to the microvias 61 shown in FIGS. 11A and 11B. The microvias can be copper filed vias to provide better thermal conduction. The holes in the top, second, and bottom layer 51, 52, 53 can be included to mount a heatsink (not shown in FIG. 10) to the to the inlay PCB 50. The copper plane 56b connected to the power connection −Vdc can extend along the bottom layer to help reduce or minimize stray inductance of the power loop. In addition, the bottom layer 53 with the copper plane 56b connected to the power connection −Vdc can be attached to a heatsink without a TIM layer because the heatsink can be connected to the bottom layer 53, significantly reducing or minimizing the thermal resistance between inlay PCB 50 and the heatsink.

FIG. 11A shows an example of a circuit assembly that includes an inlay PCB 60 with a copper inlay that is thermally connected by the microvias 61 to the switching devices S1 and S2, which can be, for example, GaN switching devices, on the top surface of the inlay PCB 60. FIG. 11A shows that the inlay PCB 60 can be attached to a heatsink 62. FIG. 11B shows that the inlay PCB 60 can alternatively include an metal substrate 63 rather than a heatsink. The metal substrate 63 can be a copper substrate or can be any other suitable metal or alloy. Alternatively, the metal substrate 63 can also be an integrated IMS. A thermal path can be provided between the switching devices S1 and S2 to the metal substrate 63 via the microvias 61 and either heavy copper planes or copper inlays of the inlay PCB 60.

Due to the relatively large surface area of the copper inlays in the inlay PCB 60, the copper inlays can effectively transfer and spread the heat away from switching devices S1 and S2. Therefore, with an inlay PCB 60, the thermal resistance of the inlay PCB 60 can be significantly reduced. To achieve the best thermal performance of the inlay PCB 60, the gate driver circuit can be located on a separate board so that the layout of the copper inlay can be improved or optimized. FIG. 10 shows that the gate driver circuit shown in FIG. 9 has been removed from the inlay PCB. The gate driver circuitry can be located on a separate gate-driver PCB (not shown). FIG. 10 shows possible locations for surface mount connectors 54 that can be used to connect the gate signals from the gate-driver PCB.

In a higher power density design, an inlay PCB 60 can be combined with a metal substrate 63 that is an IMS as discussed above with respect to FIG. 11B. In this configuration, there is a copper inlay in the second layer and a copper substrate in the bottom layer. No separate heatsink is required because the metal substrate 63 functions as a heatsink. Configured with these preferred embodiments of the present invention, a circuit assembly can have a very high power density and can be made simpler.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

1. A circuit assembly comprising:
a printed circuit board (PCB) with a metal inlay and an integrated metal substrate on a first side of the metal inlay;
a switching device connected to a second side of the metal inlay opposite to the first side; and
a thermal path between the switching device and the metal substrate via the metal inlay.

2. The circuit assembly according to claim 1, wherein the PCB includes copper-filled vias located beneath the switching device.

3. The circuit assembly according to claim 2, wherein the copper-filled vias provide a portion of the thermal path between the switching device and the metal substrate.

4. The circuit assembly according to claim 1, wherein the metal inlay is electrically connected to the switching device.

5. The circuit assembly according to claim 1, the metal substrate is an insulated metal substrate (IMS).

6. The circuit assembly according to claim 5, wherein the IMS includes copper.

7. The circuit assembly according to claim 1, wherein the metal inlay includes copper.

8. The circuit assembly according to claim 1, wherein
the metal inlay includes multiple portions, and
each of the multiple portions is connected to a different circuit node on the PCB.

9. The circuit assembly according to claim 1, wherein the switching device is a gallium nitride switching device.
